(19) United States
(12) Patent Application Publication
(10) Pub. No.: US 2017/0324166 A1
(43) Pub. Date: Nov. 9, 2017

(54) DEVICES AND METHODS OF FABRICATION OF SINUSOIDAL PATTERNED SILICON DIOXIDE SUBSTRATES

(71) Applicant: THE REGENTS OF THE UNIVERSITY OF CALIFORNIA, Oakland, CA (US)

(72) Inventors: Kang L. Wang, Santa Monica, CA (US); Aryan Navabi-Shirazi, Los Angeles, CA (US); Mohsen Yazdani, Los Angeles, CA (US)

(73) Assignee: THE REGENTS OF THE UNIVERSITY OF CALIFORNIA, Oakland, CA (US)

(21) Appl. No.: 15/598,546

(22) Filed: May 18, 2017

Related U.S. Application Data
(63) Continuation of application No. PCT/US2015/062039, filed on Nov. 21, 2015.
(60) Provisional application No. 62/083,225, filed on Nov. 22, 2014.

(51) Int. Cl. H01Q 9/04; G03F 7/20; C01B 32/186; C01B 33/12; H01Q 3/01; H01Q 1/36

(52) U.S. Cl. CPC H01Q 9/0407; H01Q 3/01; H01Q 1/368; C01B 32/186; C01B 33/126; G03F 7/2004

(57) ABSTRACT

A method for fabricating nanoscale patterned oxide substrates and devices incorporating the substrates are provided. Highly periodic or non-periodic sinusoidal patterns and other fine oxide patterns are formed on the surface of a suitable base such as silicon. Fine oxide surface patterns are created with photolithography, etching and three different oxide formation events. Thin layers of conductor materials including graphene and metals can be applied to the oxide surface patterns of the substrate and conform to the pattern allowing morphology and physical properties the conductor layer to be tuned. Control over device characteristics is demonstrated by varying the dimensions, strain, orientation, wavelength and amplitude of graphene sheet corrugations. A patch antenna device with a periodic sinusoidal graphene sheet on a silicon oxide substrate mounted to a ground plane was demonstrated.

### CROSS-REFERENCE TO RELATED APPLICATIONS

This application claims priority to, and the benefit of, U.S. provisional patent application Ser. No. 62/083,225 filed on Nov. 22, 2014, incorporated herein by reference in its entirety.

### STATEMENT REGARDING FEDERALLY SPONSORED RESEARCH OR DEVELOPMENT

Not Applicable

### INCORPORATION-BY-REFERENCE OF COMPUTER PROGRAM APPENDIX

Not Applicable

### BACKGROUND

### 1. Technical Field

The present technology pertains generally to methods of production of patterned graphene and associated devices and more particularly to devices and methods for producing patterned conductor films such as graphene sheets with tunable periodic and/or non-periodic sinusoidal corrugations. Control over the orientation, wavelength and amplitude of the graphene sheet corrugations allows control over a variety of device characteristics.

### 2. Background

Graphene has a sheet structure of carbon atoms that have been tightly packed into a two-dimensional honeycomb crystal lattice. The geometrical structure of graphene provides a number of useful mechanical, chemical and electrical characteristics that could be adapted to a wide range of potential applications including nanoelectronics, nanophotonics, and sensor technologies. For example, charge carriers (electrons or holes) disperse linearly as a result of the geometrical structure of graphene and low-energy excitations can be described by the two-dimensional, massless Dirac equation. Charge carriers can travel thousands interatomic distances without scattering. However, perturbations in the Dirac equation can occur with lattice deformations producing changes in the mobility of electrons between sub-lattices.

Spontaneous nanometer scale ripples have been observed in flakes of suspended graphene that can reach peaks of around 1 nm. Corrugations or ripples are an intrinsic feature of graphene sheets and have been shown to strongly influence the electronic properties of the sheets by inducing effective magnetic fields and by changing local potentials. The curvature of these intrinsic ripples can cause electrochemical potentials to vary spatially due to rehybridization effects which can also affect the density of states. Intrinsic ripple sizes have also been characterized by applying in-plane magnetic fields.

Since the vibrational properties, electronic structure, transport characteristics and other physical characteristics of graphene are impacted by the appearance of ripple structures, control over various graphene functionalities should be possible with control over the morphology of the graphene sheets. For example, device designs based on local strain and bandgap engineering should be possible by controlling ripple structures in the graphene structure.

Experimental work on high aspect ratio periodically rippled graphene is limited due to the difficulty in producing and faithfully reproducing such structures. Periodically rippled graphene production has been attempted experimentally. However, the ripples have small aspect ratios or are not perfectly periodic and easily reproducible.

Accordingly, there is a need for tunable devices and methods of producing corrugated graphene sheets with both periodic and/or non-periodic, non-intrinsic ripples that will allow control over device characteristics including the electron transport and optics of graphene sheets.

### BRIEF SUMMARY

The present technology provides a highly periodic sinusoidal silicon dioxide substrates fabricated by patterning a silicon base into a sinusoidal SiO₂ substrate. The substrates can be patterned with both periodic and/or non-periodic ripples or corrugations, for example. Other oxide patterns are also possible that are designed to impart selected features or morphologies to layers of material that have been applied to the patterned surface. In one illustration, the substrates can be used to produce graphene sheets patterned with corrugations or ripples that have tunable dimensions that can be used to provide functional elements with selected properties for use in a variety of graphene based devices.

The sinusoidal silicon dioxide substrates can be used in microfluidics, sensors, and other electronic and micromechanical devices. Sinusoidal metallic gratings can be realized by depositing a thin conducting film with periodicities of the patterned substrate ranging in the visible light wavelength. Metallic gratings can be used in photonics for Smith-Purcell radiation. It can also be used for the formation of microstrip patch and dual band antennas, for example.

Additionally, one or more graphene layers can be transferred to the top of the sinusoidal substrate, creating a sinusoidal graphene sheet or laminate. The substrates can also be used with materials other than graphene, such as metals or conductive polymers. The conformed layers of conductor material can remain on the patterned oxide surface or the patterned material can be separated from the substrate in some instances. These new structures can be used for various applications in electronics, photonics, and electromagnetics. For example the sinusoidal graphene sheet can be used for radiation in the GHz or THz range.

To illustrate the process, highly periodic and pure sinusoidal stacked graphene sheets with a periodicity of 600 nm and a depth of 200 nm were produced using a patterned substrate. The periodicity and sinusoidal pattern was realized by transferring three layers of chemical vapor deposition (CVD) graphene on top of a SiO₂ substrate that was patterned into a sinusoidal substrate.

First, a silicon wafer (100) was thermally oxidized to grow a 90 nm oxide to serve as an etch mask. A stepper was used to perform photolithography using ULTRA-i™ 123 i-line photoresist and pattern 300 nm wide trenches in the photoresist. Dry etching was used to etch the exposed SiO₂ etch mask and create 300 nm wide trenches in the oxide, spaced 300 nm apart, and to expose the silicon underneath. Anisotropic etching was then performed using KOH at 45° C. for 2 minutes and 30 seconds with the thermal oxide acting as an etch mask. This produced parallel V shape trenches in the silicon. The oxide etch mask was then removed using buffered oxide etching (BOE). A 300 nm thermal oxide was grown. The surface topography does not look sinusoidal at this stage. The smoother silicon under the thermal oxide was used instead by removing the 300 nm thermal oxide. After growing another thermal oxide of around 340 nm, the substrate became sinusoidal with a depth of 210 nm and a periodicity of 600 nm.

A single layer of graphene was then transferred on top of the patterned substrate. However, most of the graphene remained suspended or torn between the crests of the patterned substrate. Continuous and fully conformed graphene sheets were obtained by transferring a total of three CVD graphene layers, creating rippled trilayer stacked graphene (TLSG). Using Raman spectroscopy, the red shift in the G peak was used to determine the amount of strain in the rippled stacked graphene sheets. It was determined that the change in conductivity is directly related to the amount of strain in graphene induced by the patterned substrate.

According to one aspect of the technology, a method is provided for producing nanoscale, patterned oxide substrates that can be used for patterning graphene and other materials.

Another aspect of the technology is to provide a method for producing stacked sheets of graphene with a tunable morphology determined by the structure of the substrate.

According to another aspect of the technology, a method is provided that allows control over the electronic and other properties of patterned stacks of one or more graphene sheets by controlling the dimensions, strain and corrugations or ripples of the sheets.

Another aspect of the technology is to allow the miniaturization of devices and provide control over device characteristics by controlling the orientation, wavelength and amplitude of the graphene sheet corrugations.

Further objects and aspects of the technology will be brought out in the following portions of the specification, wherein the detailed description is for the purpose of fully disclosing preferred embodiments of the technology without placing limitations thereon.

### BRIEF DESCRIPTION OF THE SEVERAL VIEWS OF THE DRAWINGS

The technology described herein will be more fully understood by reference to the following drawings which are for illustrative purposes only:

FIG. 1 is a schematic flow diagram of a method for producing graphene sheets with controlled morphology using nanoscale patterned oxide substrates according to one embodiment of the technology.

FIG. 2A is a schematic cross-section of a patch antenna embodiment with the substrate sinusoidally corrugated in one dimension which enables miniaturization of portable device antenna, where d is the depth of the antenna, i.e. vertical distance from trough to crest, and A is the peak to peak distance or the substrate periodicity.

FIG. 2B is a detailed view of a corrugation of the device shown in FIG. 2A with a conformed graphene sheet on the substrate.

FIG. 2C is a schematic representation of a one or more periodic rippled graphene sheets that can be thought of as a series of resistors, each representing one period, Rᵣᵢₚₚ. For each resistance Rᵣᵢₚₚ, W is the width and S is the arc length is the actual length of the resistor. These dimensions may be used to calculate the ρᵣᵢₚₚ and σᵣᵢₚₚ.

FIG. 3A is a graph showing the change in conductivity (mS) of stacked layers of flat CVD graphene with changing number of graphene layers. The slope of the fitted line is 0.772 mS.

FIG. 3B is a graph depicting the observed change in conductivity of a bilayer stacked graphene (BLSG) and trilayer stacked graphene (TLSG) sheet structures. The σᵣᵢₚₚ of TLSG decreases when it is rippled, but decreases dramatically for substrates with periodicity of 1000 nm.

FIG. 4 is a graph depicting the Red shift in the G peak for the rippled TLSG structure. The red shift drastically increases for sinusoidal substrates of periodicity 1000 nm.

FIG. 5 is a graph depicting the change in calculated conductivity versus the shift in the G peak. The σᵣᵢₚₚ was calculated by normalizing the resistance of TLSG with the number of ripples and then using the arc length of the TLSG as the actual length. The change in calculated conductivity directly follows the change in the G peak location.

FIG. 6 is a graph depicting the amount of strain in rippled TLSG that was calculated assuming a 14.2 cm⁻¹ red shift for every percent strain. ρᵣᵢₚₚ is the reciprocal of σᵣᵢₚₚ. The figure shows direct correlation between the amount of strain and the change in the calculated resistivity.

FIG. 7 is a graph of return loss versus frequency for different corrugation amplitudes.

FIG. 8 is a schematic perspective view of a single port embodiment of a microstrip patch antenna with a square shaped patch.

FIG. 9 is a top view of a dual port embodiment of a microstrip patch antenna.

### DETAILED DESCRIPTION

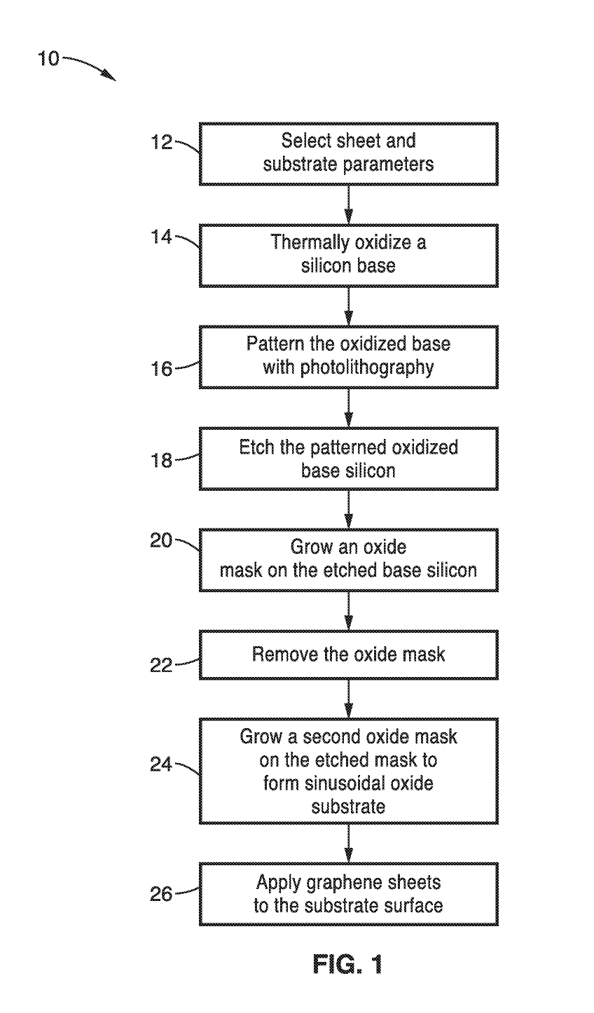

Referring more specifically to the drawings, for illustrative purposes, embodiments of the tunable substrates and methods for fabrication and use to provide graphene sheets with selected morphologies and properties or other applications are generally shown. Several embodiments of the technology are described generally in FIG. 1 through FIG. 9 to illustrate the substrates and methods. It will be appreciated that the methods may vary as to the specific steps and sequence and the devices may vary as to structural details without departing from the basic concepts as disclosed herein. The method steps are merely exemplary of the order that these steps may occur. The steps may occur in any order that is desired, such that it still performs the goals of the claimed technology.

Turning now to FIG. 1, one method 10 for producing characteristic sinusoidal graphene sheets with the fabrication and use of a specifically patterned silicon oxide substrate is generally described to illustrate the ability to control the properties of the graphene sheets with the nanoscale substrate. Although the illustration in FIG. 1 is for the fabrication of graphene structures, the substrate and methods can be adapted to layers of metals and other materials as well.

At block 12 of FIG. 1, the sheet and substrate parameters are selected. Many of these parameters will be determined by the selection of the device that will use the patterned conductor layer (graphene sheets) as an element.

The parameters of the final graphene sheet morphology can be selected to produce a structure with a desired electronic, optical or physical property or properties. For example, the sheet dimensions, strain as well as the orientation, wavelength and amplitude of the graphene sheet corrugations can be selected to produce a structure with predictable properties.

The selected parameters of the final graphene sheet structure will direct the selection of the dimensions and nanoscale patterns of the substrate that will be produced. For example, the substrate surface can have periodic or non-periodic corrugations on the surface. The corrugations can be patterned in different directions. Any set of nanoscale surface features or patterns can be selected at block 12.

The fabrication of a patterned substrate can be illustrated with the formation of a highly periodic sinusoidal silicon dioxide embodiment using the method steps of FIG. 1. A silicon base is provided of suitable dimensions defined by the intended device or device element. Preferably, a conventional silicon wafer is sized and thermally oxidized to grow an oxide on a top surface to serve as an etch mask at block 14 of FIG. 1.

The initial thermal oxide mask that was grown on the silicon base at block 14 is then patterned using conventional photolithography at block 16. In this illustration, the etch mask can be patterned with a photoresist to form parallel nanoscale trenches in the resist separated by a defined distance, preferably the same distance as the width of a trench. The width of the trench preferably should be one-half of the desired periodicity. The substrate base silicon is then fully patterned using a combination of dry and wet etching of the silicon and silicon oxide, in one embodiment.

At block 18 of FIG. 1, the patterned oxide mask is then etched to expose areas of the silicon base and to etch the silicon below. The oxide etch mask is then removed. For example, in one embodiment, dry etching can be used to etch the exposed SiO₂ etch mask and create trenches in the oxide, spaced a defined distance apart, and to expose the silicon underneath the initial oxide layer. The etched base is etched a second time to produce the trenches in the silicon. For example, the exposed silicon can be anistropically etched to form trenches or other features in the silicon base. The remaining oxide mask is then removed after the silicon base is etched.

At block 20 of FIG. 1, an oxide layer is then grown on the clean etched silicon surface that is produced at block 18. This oxide layer preferably should be one-half of the periodicity to ensure a smooth sinusoidal pattern. However, the surface topology does not appear to be sinusoidal at this stage. To complete the process, the oxide mask produced at block 20 is then etched and removed at block 22. Finally, at block 24 a second oxide mask, preferably as thick as one-half of the periodicity, is formed on the smoother silicon to form the final oxide substrate. The produced substrate has surface features that are specifically tailored for imposing a pattern on graphene sheets, metals, conductive polymers or other materials that deposited on the surface, for example.

At block 26 of FIG. 1, one or more graphene sheets are deposited on the prepared oxide surface of the substrate and the sheets conform to the surface features of the oxide surface of the substrate. The transfer of the graphene sheets can be accomplished using a standard wet transfer process or other techniques for depositing sheets. In one embodiment the material is deposited and formed directly on the prepared substrate surface. The conformed graphene or other material may remain on the surface of the substrate to support the material. In other embodiments, the conformed layer of material is separated from the substrate and used independently.

The technology described herein may be better understood with reference to the accompanying examples, which are intended for purposes of illustration only and should not be construed as in any sense limiting the scope of the technology described herein as defined in the claims appended hereto.

### Example 1

in order to demonstrate the method of formation of a patterned substrate, a highly periodic sinusoidal silicon dioxide substrate was formed by patterning a silicon base into a sinusoidal SiO₂ substrate using steps shown in FIG. 1. First, a silicon wafer (100) was thermally oxidized to grow a 90 nm oxide to serve as an etch mask. A stepper was used to perform photolithography using ULTRA-i™ 123 i-line photoresist and 300 nm wide trenches, 300 nm apart, were patterned in the photoresist. Dry etching was used to etch the exposed SiO₂ etch mask and create 300 nm wide trenches in the oxide, spaced 300 nm apart, exposing the silicon beneath.

Anisotropic etching was then performed using KOH at 45° C. for 2 minutes and 30 seconds with the thermal oxide acting as an etch mask. This produced V shape trenches in the silicon. The remaining oxide etch mask was then removed using buffered oxide etching (BOE).

A 300 nm thermal oxide was then grown on the exposed silicon. The surface topography did not appear sinusoidal at this stage. The smoother silicon beneath the thermal oxide was used instead by removing the 300 nm thermal oxide using buffered oxide etching (BOE).

After growing another thermal oxide of around 340 nm on the silicon surface, the final substrate oxide surface became sinusoidal with a depth of 210 nm and a periodicity of 600 nm.

Imaging of the final substrate disclosed a highly repetitive uniform sinusoidal oxide substrate surface. In all images, the substrate was covered with a thin gold layer by sputtering to improve the SEM image quality. There were 25 areas patterned on a single substrate of 7×7 mm², with periodicities of 600 nm, 700 nm, 800 nm, 900 nm, and 1000 nm, five of each periodicity. Each patterned area was 200 μm by 350 μm.

### Example 2

To demonstrate the use of a patterned substrate to pattern graphene, graphene sheets were prepared and deposited on the surface of the highly periodic sinusoidal silicon dioxide substrate that was produced in Example 1.

Graphene that was grown by chemical vapor deposition (CVD) was transferred on to the surface of the patterned substrate using a standard wet transfer process. SEM images of the graphene after removing the PMMA layer on top indicated that parts of the graphene film over the troughs were suspended or broken. The images indicated that the graphene sheet had been stretched and strained upon transfer to the patterned substrate and it remained strained when it collapsed into the troughs.

Hall bar structures were fabricated by patterning the graphene through photolithography. As expected, the graphene showed open circuit behavior due to tearing from the transfer or Hall bar fabrication process. Use of e-beam lithography (EBL) was not very practical since finding continuous areas of graphene with an optical microscope on a substrate patterned with periodicity of 600 nm was not feasible.

Another layer of CVD graphene was then transferred on top of the existing graphene layer disposed on the substrate surface. It was possible to observe and measure the resistance of the bilayer stacked graphene (BLSG) since gaps in the first graphene layer was filled with the second graphene sheet. The word “stacked” is used to differentiate the film from bilayer graphene that is formed naturally. SEM images that were taken of the bilayer structure showed portions of graphene were still suspended while others had collapsed down in the troughs.

A third layer of graphene was then transferred to the top of the BLSG surface and an almost complete conformity of the graphene films was observed with the placement of the third layer. The percentage of observed suspended areas was significantly reduced with the transfer and processing of the third layer. SEM images were taken of the sinusoidal tri-layer stacked graphene.

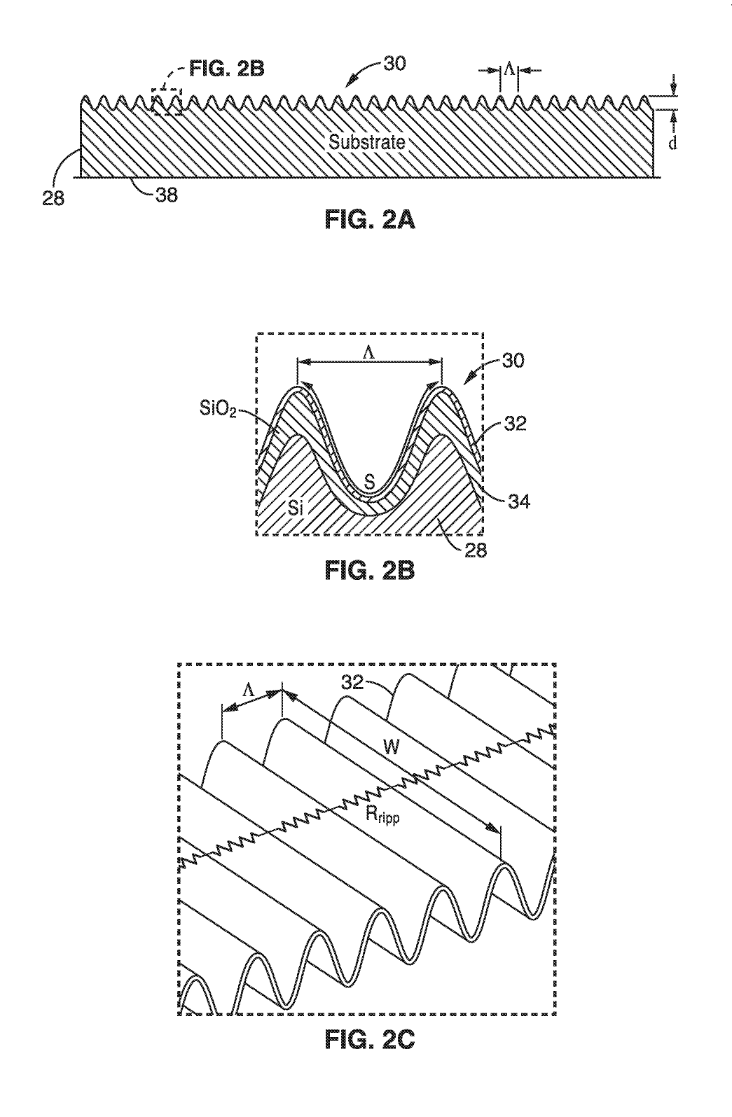

An embodiment of the substrate with a sinusoidally rippled periodic (e.g., corrugated) surface is shown schematically in FIG. 2A through FIG. 2C. A schematic cross-section of a patch antenna is used as an example to illustrate this configuration. In FIG. 2A, a substrate 28 is shown patterned with a periodically rippled (corrugated) surface 30 in one dimension, where d is the depth of the antenna corrugation, i.e., vertical distance from trough to crest, and A is the peak to peak distance or the substrate periodicity. A layer 32 of one or more graphene sheets is disposed on the surface of the substrate as is also shown. FIG. 2B provides a detailed view of a section of the corrugated surface 30, where, in this embodiment, the antenna comprises a silicon base substrate 28 with an oxide surface 34 overlaid with one or more graphene sheets to form layer 32. It will be appreciated that the term “layer” as used herein can encompass multiple layers as well, and that multiple graphene sheets can be considered a single layer of multiple sheets or multiple layers of a single sheet.

FIG. 2C shows a schematic representation of one or more periodic corrugated or rippled graphene sheet layers 32 used for testing. The corrugated graphene sheets can be thought of as a series of resistors, each representing one period, Rᵣᵢₚₚ. For each resistance Rᵣᵢₚₚ, W is the width and S is the arc length is the actual length of the resistor as shown in FIG. 2B. These dimensions may be used to calculate the ρᵣᵢₚₚ and σᵣᵢₚₚ.

To measure the conductivity of the rippled graphene sheets, the 4-terminal resistance R_{4T} to the number of ripples was normalized. The channel length L_{ch} of rippled TLSGs was observed to be 280 μm. The number of ripples within the channel length varied for each periodicity, Λᵢ, since the channel length was a constant 280 μm. Each period can be thought of as a resistor

$${R}_{ripp , i} = \frac{{R}_{4 T , i}}{{L}_{ch} \text{/} {Λ}_{i}} ,$$

where i is for a device with a specific ripple periodicity Λᵢ, ranging from 600 nm to 1000 nm with steps of 100 nm.

The conductivity for one period of sinusoidal graphene can be calculated using the width of the rippled TLSG sheet, W, which was 180 μm, and the arc length,

$${S}_{i} = {\int }_{0}^{{Λ}_{ripp , i}} \sqrt{1 + {f}_{i}^{′} ( x )} dx$$

as the actual length where fᵢ(x)=100 sin(2π/Λ_{ripp,i}). It should be noted that for the 5 different periodicities, 600 nm to 1000 nm with steps of 100 nm, the same amplitude was used since they were all etched for the same depth of 200 nm. So the rippled TLSG with periodicity of 600 nm has a depth of 200 nm and so does the one with 1000 nm periodicity.

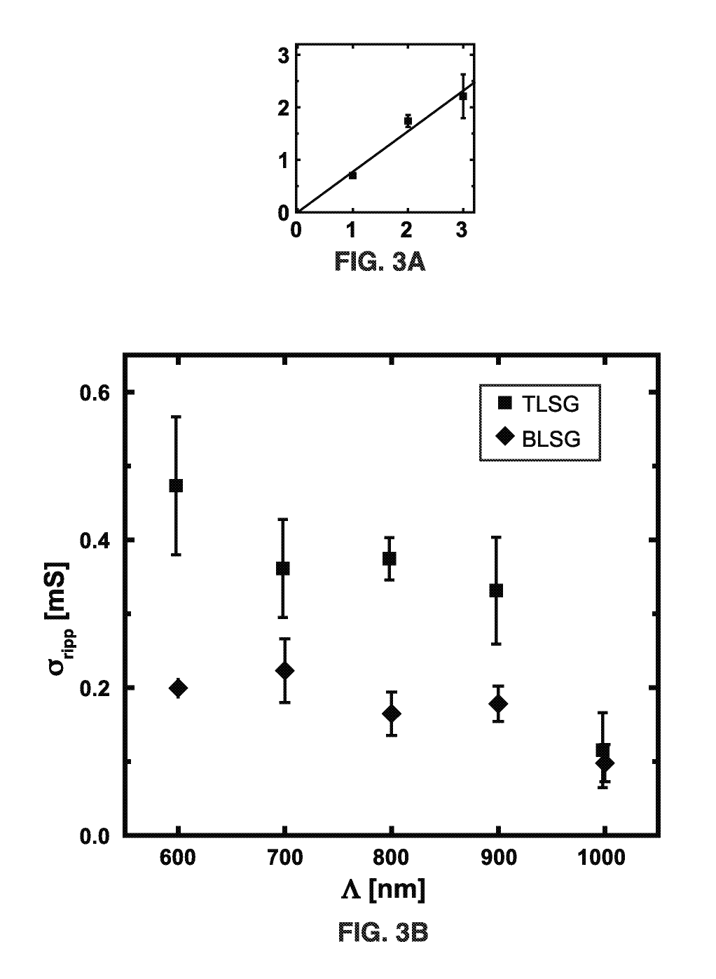

A graph depicting the observed change in conductivity (σᵣᵢₚₚ) of a bilayer stacked graphene (BLSG) and trilayer stacked graphene (TLSG) sheet structures for different ripple periodicities is shown in FIG. 3B. The calculated conductivity was: σ_{ripp,i}=1/Rᵣᵢₚₚ(Sᵢ/W).

The same CVD graphene was used for different periodicities and they all went through the same process. It was observed from the graph of FIG. 3B that the σᵣᵢₚₚ of TLSG decreases when it is rippled, but decreases dramatically for substrates with periodicity of 1000 nm. The graph of FIG. 3A shows the change in conductivity (mS) of stacked layers of flat CVD graphene with the changing number of graphene layers.

The conductivity of a flat BLSG and TLSG was 1.74 mS and 2.2 mS, respectively. The slope of the fit in the graph of FIG. 3B was 0.772 mS. Apart from the SEM images, the relatively large error bars for σᵣᵢₚₚ of rippled BLSG also reveal the randomness in conformity of BLSG, whereas the smaller error bars in conductivity of rippled TLSG showed the uniformity of the conformed graphene sheets.

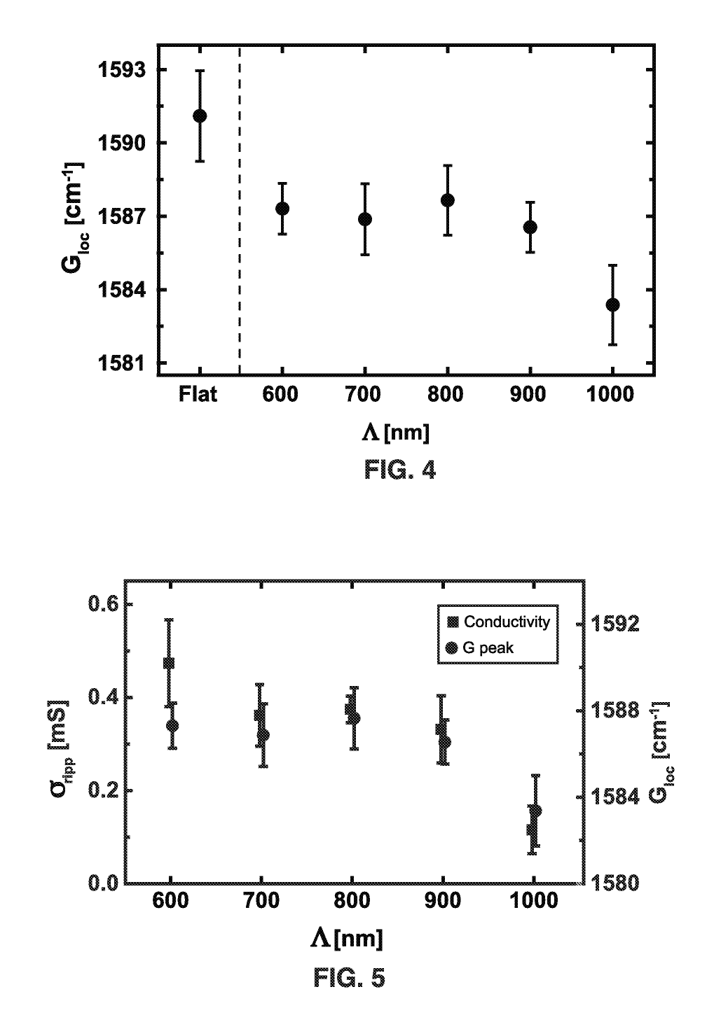

It is believed that the observed change in resistivity was due to the rippling of the graphene layers once it was conformed to the substrate. To confirm this, Raman spectroscopy was used to determine the red shift in the G peak which would reveal the amount of strain on graphene. FIG. 4 shows the location of the G peak, G_{loc}, of TLSG for the different substrate periodicities. As a reference, the G_{loc} for flat TLSG has been included in the figure. It can be seen from FIG. 4 that the G peak for rippled TLSGs had red shifted but there is a significant shift for sinusoidal substrates with periodicity of 1000 nm.

FIG. 5 shows the correlation between the G peak shift and the change in σᵣᵢₚₚ. Assuming 14.2 cm⁻¹ red shift for every percent of strain, the amount of strain was calculated for each periodicity. The σᵣᵢₚₚ was calculated by normalizing the resistance of TLSG with the number of ripples and then using the arc length of the TLSG as the actual length. The change in calculated conductivity directly followed the change in the G peak location.

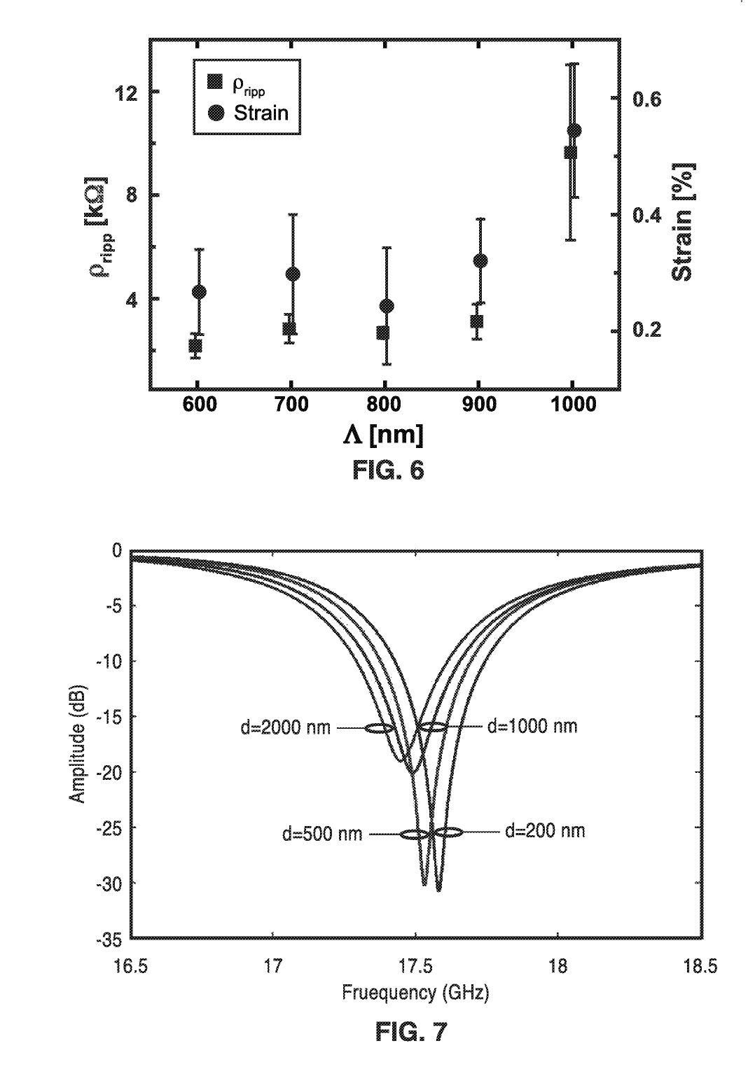

FIG. 6 is a graph depicting the amount of strain in rippled TLSG that was calculated assuming a 14.2 cm⁻¹ red shift for every percent strain. σᵣᵢₚₚ is the reciprocal of σᵣᵢₚₚ. The figure shows direct correlation between the amount of strain and the change in the calculated resistivity. Specifically, FIG. 6 shows the amount of strain in TLSG is directly correlated to the change in ρᵣᵢₚₚ=1/σᵣᵢₚₚ. This confirms that the rippling of graphene, which causes strain in graphene, results in a change of resistivity. However the way in which the amount of strain changes with respect to the substrate periodicity was not clear and may be due to the transfer process or could have more fundamental reasons, where the strain and conductivity of 800 nm period TLSG has increased and then decreased again.

Another point of interest was the observed sudden change in strain and conductivity in TLSG with periodicity of 1000 nm. This could also be due to more fundamental reasons residing in the mechanical properties of graphene, such as the best pattern graphene conformation.

### Example 3

Corrugated substrate and conductive structures can be fabricated with dimensions that produce a variety of functions. One illustration is the application of corrugated/rippled structures in a 1D and 2D microstrip patch antenna. This feature allows for miniaturization as well as dual band application of microstrip patch antenna. FIG. 2A depicts schematically a one dimensional patch antenna that was fabricated and tested using an electromagnetic simulator software called HFSS. As seen in FIG. 2A, a layer 30 of one or more graphene sheets is applied to the patch surface of substrate 28 which is sinusoidally rippled or corrugated. As illustrated in FIG. 2A and FIG. 2B, the dimension d is the depth of the antenna, i.e., vertical distance from trough to crest, and Λ is the peak to peak distance or the substrate periodicity.

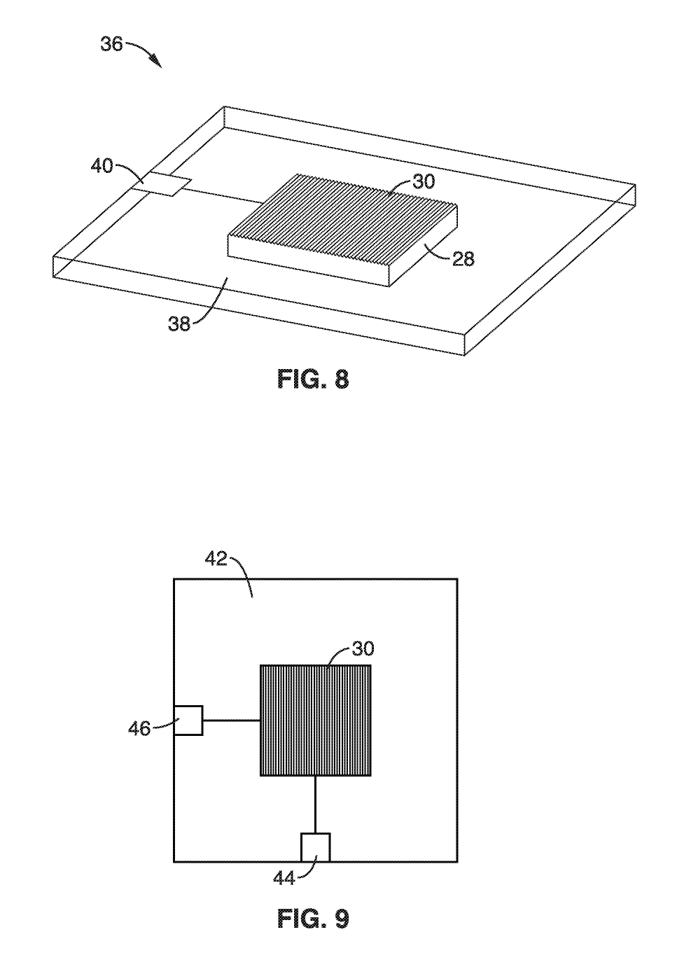

The ability to reduce the size of the patch antenna structure was demonstrated in the test design shown in FIG. 8. Test results of the return loss versus frequency for different ripple amplitudes are shown in the graph of FIG. 7.

The patch antenna design 36 shown in FIG. 8 has a square substrate 28 with equal length and width dimensions and a uniformly periodic sinusoidal surface 30 that includes a layer of conformed graphene 32 over an oxide 34 as shown in FIG. 2B and FIG. 2C. The substrate is mounted or positioned adjacent to a ground plane 38 and a port 40 is electrically coupled to the conductive graphene layer 32.

The fabricated antenna size was kept constant at 4 mm×4 mm, and by changing the amplitude of ripples, d, frequency tuning was possible, which indicated that size reduction in the microstrip patch antenna was also possible. The radiation pattern of the antenna 36 of FIG. 8 and its polar plot were also evaluated.

### Example 4

Referring now to FIG. 2A through FIG. 2C and FIG. 9, another application of the technology is illustrated with a two port microstrip patch antenna designed to excite both TM₁₀ and TM₀₁ modes. The square shaped antenna was designed to be rippled in one direction and flat in the other direction. As seen in the top view of FIG. 9, the silicon substrate with an oxide and conformed graphene surface 30 is mounted or positioned adjacent to a ground plane 42. Port 44 and port 46 are electrically coupled to the conductive graphene layer 32 of the corrugated surface 30.

By having two different effective lengths in each direction, the structure will have two different resonance frequency modes, i.e. a dual mode microstrip patch. With the miniaturization effect, this can be done without compromising the antenna footprint on the board chip. The structure can be rippled in both dimensions with different periodicities to achieve two different resonant frequencies. Accordingly, devices with additional modes can also be fabricated. The dimensions and sinusoidal silicon oxide substrates of various periodicities can be specifically tailored to provide patch antennas with different predictable capabilities.

### Example 5

The optical properties of graphene can also be utilized with sinusoidal structures. Corrugated graphene can act as a Bragg grating. Its Bragg wavelength is λ_{b}=2×Re(n_{eff})×period. To demonstrate the reflective properties of graphene on a sinusoidal substrate as a Bragg grating, transmission simulations of graphene coated periodic sinusoidal surfaces. The reflective index (n_{eff}) of the structure, calculated in two dimensions at 800 nm is shown in Table 1.

From the description herein, it will be appreciated that that the present disclosure encompasses multiple embodiments which include, but are not limited to, the following:

1. A method for fabricating patterned graphene sheets, the method comprising: (a) producing one or more graphene sheets; (b) fabricating a substrate with a patterned oxide surface; (c) applying the graphene sheets to the patterned oxide surface to form a layer of graphene; and (d) conforming the layer of applied graphene sheets to the surface pattern of the oxide surface.

2. The method of any preceding embodiment, further comprising: applying a second layer of graphene sheets to the first layer of graphene sheets; and conforming the first and second layers of graphene to the surface pattern of the oxide surface.

3. The method of any preceding embodiment, further comprising: applying a second layer of graphene sheets to the first layer of graphene sheets; applying a third layer of graphene sheets to the second layer of graphene sheets; and conforming the first, second and third layers of graphene to the surface pattern of the oxide surface.

4. The method of any preceding embodiment, wherein the fabricating a substrate comprises: thermally oxidizing a surface of a silicon base to form an oxidized silicon base; patterning the oxidized base with photolithography; forming the pattern in the silicon base; clearing the surface oxidization from the patterned silicon base; growing a first oxide mask on the cleaned patterned silicon base; removing the first oxide mask from the patterned silicon base; and growing a second oxide mask on the patterned silicon base to produce a final silicon substrate with a patterned oxide surface.

5. The method of any preceding embodiment, wherein the forming the pattern in the silicon base comprises: dry etching the oxidized base to expose the silicon base in the form of the pattern; anistropically etching the exposed silicon pattern to etch the pattern into the silicon base; and removing remaining oxide from the surface of the oxidized base.

6. The method of any preceding embodiment, wherein the pattern in the silicon comprises parallel trenches equally spaced apart.

7. The method of any preceding embodiment, wherein a width of each trench is equal to a distance between each trench.

8. The method of any preceding embodiment, wherein the pattern of parallel trenches in the silicon comprises trenches with a “V” shaped cross-section.

9. The method of any preceding embodiment, further comprising: identifying a graphene sheet morphology; and forming a patterned oxide surface on the substrate of the same pattern as the identified graphene sheet morphology.

10. The method of any preceding embodiment, wherein the identifying a graphene sheet morphology comprises: selecting a corrugated sheet morphology; and selecting an orientation, wavelength and amplitude of the graphene sheet corrugations.

11. The method of any preceding embodiment, wherein the selecting the orientation, wavelength and amplitude of the graphene sheet corrugations is made to provide a characteristic graphene sheet conductivity.

12. The method of any preceding embodiment, wherein the selecting the orientation, wavelength and amplitude of the graphene sheet corrugations is made to provide a characteristic strain on a graphene sheet layer.

13. The method of any preceding embodiment, further comprising: selecting substrate length and width dimensions.

14. The method of any preceding embodiment, wherein the pattern of the patterned oxide surface comprises a periodic sinusoidal oxide surface pattern.

15. The method of any preceding embodiment, wherein the pattern of the patterned oxide surface comprises a non-periodic sinusoidal oxide surface pattern.

16. A method for fabricating a microstrip patch antenna, the method comprising: (a) fabricating a silicon substrate with a periodic sinusoidal patterned oxide surface; (b) conforming at least one layer of a conductor to the surface pattern of the patterned oxide surface of the silicon substrate; (c) positioning the silicon substrate adjacent to a ground plane; and (d) coupling the conductive layer to a port.

17. The method of any preceding embodiment, wherein the conductor layer is a conductor selected from the group of conductors consisting of a metal, graphene and a conductive polymer.

18. The method of any preceding embodiment, further comprising: selecting the orientation, wavelength and amplitude of the sinusoidal conductor pattern; and selecting length and width dimensions of the patch to tune the frequency of the antenna.

19. A method for fabricating a substrate with a patterned oxide surface, the method comprising: (a) thermally oxidizing a surface of a silicon base to form an oxidized silicon base; (b) patterning the oxidized base with photolithography; (c) forming the pattern in the silicon base; (d) clearing the surface oxidization from the patterned silicon base; (e) growing a first oxide mask on the cleaned patterned silicon base; (f) removing the first oxide mask from the patterned silicon base; and (g) growing a second oxide mask on the patterned silicon base to produce a final silicon substrate with a patterned oxide surface.

20. The method of any preceding embodiment, wherein the forming the pattern in the silicon base comprises: dry etching the oxidized base to expose the silicon base in the form of the pattern; anistropically etching the exposed silicon pattern to etch the pattern into the silicon base; and removing remaining oxide from the surface of the oxidized base.

21. The method of any preceding embodiment, wherein the pattern in the silicon comprises parallel trenches equally spaced apart.

22. The method of any preceding embodiment, wherein a width of each trench is equal to a distance between each trench.

23. The method of any preceding embodiment, wherein the pattern of parallel trenches in the silicon comprises trenches with a “V” shaped cross-section.

24. An apparatus comprising: (a) a silicon substrate with a patterned silicon dioxide surface; and (b) a layer of graphene disposed on the silicon dioxide surface of the silicon substrate conforming to the silicon dioxide pattern.

25. The apparatus of any preceding embodiment, wherein the pattern comprises a periodic nanoscale sinusoidal pattern.

26. The apparatus of any preceding embodiment, wherein the pattern comprises a non-periodic nanoscale sinusoidal pattern.

27. The apparatus of any preceding embodiment, wherein said pattern comprises parallel trenches equally spaced apart.

28. The apparatus of any preceding embodiment, wherein a width of each trench is equal to a distance between each trench.

29. The apparatus of any preceding embodiment, wherein said pattern of parallel trenches comprises trenches with a “V” shaped cross-section.

30. A microstrip patch antenna apparatus, comprising: (a) at least one patch of one or more layers of a conductor conformed to a sinusoidal patterned oxide surface of a silicon substrate; (b) a ground plane adjacent to the silicon substrate; and (c) a port coupled to the conductor.

31. The apparatus of any preceding embodiment, wherein the conductor layer is a conductor selected from the group of conductors consisting of a metal, graphene, and a conductive polymer.

32. The apparatus of any preceding embodiment, further comprising a second port coupled to the conductor.

33. The apparatus of any preceding embodiment, wherein the patterned oxide surface comprises a periodic sinusoidal oxide surface pattern.

34. The apparatus of any preceding embodiment, wherein the patterned oxide surface comprises a non-periodic sinusoidal oxide surface pattern.

35. A highly periodic sinusoidal silicon dioxide substrate.

36. The substrate or apparatus of any preceding embodiment, wherein the substrate has a sinusoidal surface topography.

37. The substrate or apparatus of any preceding embodiment, wherein the substrate has a sinusoidal depth and periodicity.

38. The substrate or apparatus of any preceding embodiment, wherein the depth is about 210 nm and the periodicity is about 600 nm.

39. The substrate or apparatus of any preceding embodiment, wherein the substrate is a one-dimensional sinusoidal substrate.

40. The substrate or apparatus of any preceding embodiment, wherein the substrate is a component of a microstrip patch antenna.

41. The substrate or apparatus of any preceding embodiment, wherein the substrate is a component of a two port microstrip patch antenna designed to excite both TM₁₀ and TM₀₁ modes.

42. The substrate or apparatus of any preceding embodiment, wherein the substrate is a component of a rippled graphene stack.

43. A method of fabricating a silicon dioxide substrate, the method comprising patterning a silicon substrate into a sinusoidal SiO₂ substrate.

44. The method of any preceding embodiment, further comprising: (a) thermally oxidizing a silicon wafer (100) to grow a thin oxide to serve as an etch mask; (b) patterning the etch mask with photoresist to form trenches as wide as one-half of the target periodicity and spaced apart at one-half of the target periodicity; (c) dry etching the exposed SiO₂ etch mask and creating trenches in the oxide as wide as one-half of the target periodicity and spaced at one-half of the target periodicity, thereby exposing the silicon beneath; (d) anisotropically etching the silicon to form V shape trenches in the silicon; (e) removing the oxide etch mask; (f) growing a second thermal oxide with a thickness of one-half of the target periodicity; (g) removing the second thermal oxide; and (h) growing another thermal oxide with a thickness of one-half of the target periodicity; (i) wherein the substrate becomes sinusoidal with a depth of about one-third of the target periodicity.

45. The method of any preceding embodiment, further comprising: (a) thermally oxidizing a silicon wafer (100) to grow a 90 nm oxide to serve as an etch mask; (b) patterning the etch mask with photoresist to form 300 nm wide trenches, 300 nm apart; (c) dry etching the exposed SiO₂ etch mask and creating 300 nm wide trenches in the oxide, spaced 300 nm apart, thereby exposing the silicon beneath; (d) anisotropically etching the silicon to form V shape trenches in the silicon; (e) removing the oxide etch mask; (f) growing a 300 nm thermal oxide; (g) removing the 300 nm thermal oxide; and (h) growing another thermal oxide of about 340 nm; (i) wherein the substrate becomes sinusoidal with a depth of about 210 nm and a periodicity of about 600 nm.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

TABLE 1

| Position of The | Top of | Middle of | Bottom of |
|---|---|---|---|
| Input Light | Corrugation | Corrugation | Corrugation |
| u = 0 eV | 1.402107 | 1.402047 + 3.516e⁻⁴i | 1.402136 |
| u = 0.4 eV | 1.402107 | 1.401810 + 2.219e⁻³i | 1.402110 |
| u = 1 eV | 1.402107 | 1.401701 + 2.6e⁻⁴i | 1.402136 |
| air | 1.402107 | 1.402056 | 1.402121 |
| Au | 1.402107 | 1.402047 + 3.516e⁻⁴i | 1.402136 + 2.4e⁻¹⁷i |

What is claimed is:

1. A method for fabricating patterned graphene sheets, the method comprising:
(a) producing one or more graphene sheets;
(b) fabricating a substrate with a patterned oxide surface;
(c) applying one or more graphene sheets to the patterned oxide surface to form a layer of graphene; and
(d) conforming the layer of graphene to the surface pattern of the oxide surface.

2. The method of claim 1, further comprising:
applying one or more graphene sheets to the layer of graphene to form a second layer of graphene; and
conforming said layers of graphene to the surface pattern of the oxide surface.

3. The method of claim 1, further comprising:
applying one or more graphene sheets to the layer of graphene to form a second layer of graphene; and
applying one or more graphene sheets to the second layer to form a third layer of graphene; and
conforming said layers of graphene to the surface pattern of the oxide surface.

4. The method of claim 1, wherein said fabricating a substrate comprises:
thermally oxidizing a surface of a silicon base to form an oxidized silicon base;
patterning the oxidized base with photolithography;
forming the pattern in the silicon base;
clearing the surface oxidization from the patterned silicon base;
growing a first oxide mask on the cleaned patterned silicon base;
removing the first oxide mask from the patterned silicon base; and
growing a second oxide mask on the patterned silicon base to produce a final silicon substrate with a patterned oxide surface.

5. The method of claim 4, wherein said forming the pattern in the silicon base comprises:
dry etching the oxidized base to expose the silicon base in the form of the pattern;
anisotropically etching the exposed silicon pattern to etch the pattern into the silicon base; and
removing remaining oxide from the surface of the oxidized base.

6. The method of claim 4, wherein said pattern in said silicon base comprises parallel trenches equally spaced apart.

7. The method of claim 6, wherein a width of each trench is equal to a distance between each trench.

8. The method of claim 6, wherein said pattern of parallel trenches in said silicon base comprises trenches with a “V” shaped cross-section.

9. The method of claim 1, further comprising:
identifying a graphene sheet morphology; and
forming a patterned oxide surface on the substrate of the same pattern as the identified graphene sheet morphology.

10. The method of claim 9, wherein said identifying a graphene sheet morphology comprises:
selecting a corrugated sheet morphology; and
selecting an orientation, wavelength and amplitude of the graphene sheet corrugations.

11. The method of claim 10, wherein the selecting of the orientation, wavelength and amplitude of the graphene sheet corrugations is made to provide a characteristic graphene sheet conductivity.

12. The method of claim 10, wherein the selecting of the orientation, wavelength and amplitude of the graphene sheet corrugations is made to provide a characteristic strain on a graphene sheet layer.

13. The method of claim 10, further comprising:
selecting substrate length and width dimensions.

14. The method of claim 9, wherein said pattern of said patterned oxide surface comprises a periodic sinusoidal oxide surface pattern.

15. The method of claim 9, wherein said pattern of said patterned oxide surface comprises a non-periodic sinusoidal oxide surface pattern.

16. A method for fabricating a microstrip patch antenna, the method comprising:
(a) fabricating a silicon substrate with a periodic sinusoidal patterned oxide surface;
(b) conforming at least one layer of a conductor to the surface pattern of the patterned oxide surface of the silicon substrate;
(c) positioning the silicon substrate adjacent to a ground plane; and
(d) coupling the conductive layer to a port.

17. The method of claim 16, wherein said conductive layer is a conductor selected from the group of conductors consisting of a metal, graphene and a conductive polymer.

18. The method of claim 16, further comprising:
selecting the orientation, wavelength and amplitude of the sinusoidal conductor pattern; and
selecting length and width dimensions of the patch to tune the frequency of the antenna.

19. A method for fabricating a substrate with a patterned oxide surface, the method comprising:
(a) thermally oxidizing a surface of a silicon base to form an oxidized silicon base;
(b) patterning the oxidized base with photolithography;
(c) forming the pattern in the silicon base;
(d) clearing the surface oxidization from the patterned silicon base;
(e) growing a first oxide mask on the cleaned patterned silicon base;
(f) removing the first oxide mask from the patterned silicon base; and
(g) growing a second oxide mask on the patterned silicon base to produce a final silicon substrate with a patterned oxide surface.

20. The method of claim 19, wherein said forming the pattern in the silicon base comprises:
dry etching the oxidized base to expose the silicon base in the form of the pattern;
anisotropically etching the exposed silicon pattern to etch the pattern into the silicon base; and
removing remaining oxide from the surface of the oxidized base.

21. The method of claim 19, wherein said pattern in said silicon base comprises parallel trenches equally spaced apart.

22. The method of claim 21, wherein a width of each trench is equal to a distance between each trench.

23. The method of claim 21, wherein said pattern of parallel trenches in said silicon base comprises trenches with a “V” shaped cross-section.

24. An apparatus comprising:
(a) a silicon substrate with a patterned silicon dioxide surface; and
(b) a layer of graphene disposed on said silicon dioxide surface of said silicon substrate conforming to the silicon dioxide pattern.

25. The apparatus of claim 24, wherein said pattern comprises a periodic nanoscale sinusoidal pattern.

26. The apparatus of claim 24, wherein said pattern comprises a non-periodic nanoscale sinusoidal pattern.

27. The apparatus of claim 24, wherein said pattern comprises parallel trenches equally spaced apart.

28. The apparatus of claim 27, wherein a width of each trench is equal to a distance between each trench.

29. The apparatus of claim 27, wherein said pattern of parallel trenches comprises trenches with a “V” shaped cross-section.

30. A microstrip patch antenna apparatus, comprising:
(a) at least one patch of one or more layers of a conductor conformed to a sinusoidal patterned oxide surface of a silicon substrate;
(b) a ground plane adjacent to the silicon substrate; and
(c) a port coupled to the conductor.

31. The apparatus of claim 30, wherein said conductor layer is a conductor selected from the group of conductors consisting of a metal, graphene, and a conductive polymer.

32. The apparatus of claim 30, further comprising a second port coupled to the conductor.

33. The apparatus of claim 30, wherein said patterned oxide surface comprises a periodic sinusoidal oxide surface pattern.

34. The apparatus of claim 30, wherein said patterned oxide surface comprises a non-periodic sinusoidal oxide surface pattern.
